(19) United States
(12) Patent Application Publication
(10) Pub. No.: US 2006/0232281 A1
(43) Pub. Date: Oct. 19, 2006

(54) Method and device for determining the resonant frequency of resonant piezoelectric sensors

(76) Inventors: Ferrari Vittorio, Brescia (IT); Marioli Daniele, Brescia (IT); Taroni Andrea, Brescia (IT)

Correspondence Address: YOUNG & THOMPSON, 745 SOUTH 23RD STREET, 2ND FLOOR, ARLINGTON, VA, 22202, US

(21) Appl. No.: 10/549,327

(22) PCT Filed: Mar. 16, 2004
(86) PCT No.: PCT/IB04/00748

§ 371 Date: May 19, 2006

(30) Foreign Application Priority Data
Mar. 18, 2003 (IT) MI2003A000514

(51) Int. Cl. G01R 27/28

(52) U.S. Cl. 324/652

(57) ABSTRACT

A method and a device are disclosed to determine the value of the resonant frequency of a resonant sensor subject to an acoustomechanical and/or dielectric load. The sensor is simultaneously and constantly excited at two different frequencies, the first of which is the series resonant frequency, while the second is introduced to detect and compensate the sensor parallel capacitance in an automatic and continuous way.

### FIELD OF THE INVENTION

The present invention relates to a method and a device for determining the resonant frequency of piezoelectric resonant sensors subject to a load.

### BACKGROUND OF THE INVENTION

Piezoelectric resonant sensors based on AT-cut quartz crystals vibrating in thickness-shear mode (TSM) are used as quartz-crystal microbalances (QCM), film-thickness monitors, sensors for physical-chemical properties of fluids, and as transduction devices for chemical and biochemical sensors.

Quartz crystal resonant sensors are widely used in the chemical, medical, biotechnology, environmental, food, materials, and process control fields.

The primary output signal of this kind of sensors is the crystal resonant frequency, which needs to be accurately determined since it directly relates to the quantity to be measured.

To this purpose, oscillator circuits are typically used in which the crystal is inserted as the frequency-controlling element. However, when the sensor is subject to heavy acoustic and/or dielectric loads, such for measurements in contact with liquids or with viscoelastic media, the sensor resonant frequency and the output frequency of the oscillator circuit can become significantly different, thereby resulting in large inaccuracies and performance degradation.

As a limiting case, under high damping, the oscillator may stop operating properly and cease to sustain oscillations, therefore restricting the sensor operating range.

Such a situation can be represented by an extension of the equivalent circuit known in the literature as the BVD (Butterworth-Van Dyke) model, in which the characteristic parameters of a sensor subject to a load include a first capacitance representing the electrical behavior of the sensor associated to the intrinsic capacitance of the crystal, and a second capacitance resulting from contact with, or immersion into, a liquid whose conductance is assumed to be negligible. Both such capacitances in the extended BVD model are connected in parallel and they together form the so-called sensor parallel, or static, capacitance.

The parallel capacitance, whose effect combines to the increase of dissipation losses caused by the load, is the parameter that negatively affects the determination of the quantity to be measured, that is the sensor resonant frequency, and therefore the parallel capacitance has to be compensated for improving the measurement accuracy.

Oscillator circuits are already known in the literature that introduce the compensation of the sensor parallel capacitance. However, in such known oscillator circuits the compensation implies a manual adjustment which is time consuming and error prone. Moreover, such known oscillator circuits do not allow to measure the value of the compensated capacitance, which, on the contrary, can be of significant interest in several applications.

Examples of studies on the compensation of the sensor parallel capacitance have been carried out by the inventors themselves. Reference can be made, for instance, to “Oscillator Circuit Configuration for Quartz-Crystal-Resonator Sensors Subject to Heavy Acoustic Load, Electronics Letters, 36, 7 (2000); “Improving the Accuracy and Operating Range of Quartz Microbalance Sensors by a purposely Designed Oscillator Circuit”—IEEE TRANS. ON INSTR. AND MEASUR., Vol. 50, no. 5, October 2001; and “Accuracy and Range Limitations in Oscillator-Driven QCM Sensors”—Proceedings of 7th National Conference on Sensors and Microsystems, Bologna, 4-6 Feb. 2002.

In such studies, an oscillator circuit was proposed which includes a section working as a negative capacitance that is summed to the sensor parallel capacitance, thereby removing the perturbing effects that prevent the accurate measurement of the sensor resonant frequency.

This approach, though provides satisfying results, brings about some limitations. In fact, the particular configuration adopted to simulate the negative capacitance in some of the above referenced studies can become unstable under certain circumstances; moreover, in none of the circuits of the above referenced studies the sensor has one terminal connected to ground, which instead would be desirable in several electrochemical and biological applications.

A different approach to compensate for the parallel capacitance has been proposed by A. Arnau et al. (“Circuit for continuous motional series resonant frequency and motional resistance monitoring of quartz crystal resonators by parallel capacitance compensation” REV. OF SCIENT. INSTR.—Vol. 73, no. 7—July 2002) introducing a circuit which, however, requires a number of lengthy calibration operations to be performed with the unperturbed sensor. A solution is also mentioned which would enable the automation of the calibration steps of the system and the parallel capacitance compensation, but this would make the circuit even more complex and costly.

Anyway, none of the oscillator configurations so far proposed has made it possible the determination of the instantaneous value of the compensated capacitance, which is an additional and very important parameter.

As an alternative to the use of oscillator circuits, the impedance spectrum of the sensor can be measured by means of impedance analyzers. They, however, are costly instruments, require specialized personnel to operate them, and, as such, are essentially limited to laboratory use.

### SUMMARY OF THE INVENTION

The task of the present invention is to propose a method and a device that offer the typical advantages provided by the oscillators in terms of compactness, ease of use for unspecialized personnel, and low cost, while, at the same time, overcoming the limitations of the systems known to date.

Within the scope of this task, one object of the present invention is to propose a method which allows to determine with very high accuracy the value of the resonant frequency of a resonant sensor subject to an acoustic and/or dielectric load.

Another object of the present invention is to propose a method of the above cited type which enables to take extremely accurate measurements even in the cases where the resonant sensor is subject to high damping.

A further object of the present invention is to propose a method of the above cited type which enables to make the compensation of the sensor parallel capacitance of a resonant sensor automatic.

Still another object of the present invention is to indicate a device which is low-cost and easy to implement and use as to determine in a fully automated way the value of the resonant frequency of a resonant sensor subject to an acousto-mechanical and/or dielectric loads

These objects are achieved by the present invention, which relates to a method for determining the value of the resonant frequency of a loaded resonant sensor in accordance with claim 1.

In order to obtain a high measurement accuracy, the proposed technique to compensate the sensor capacitance introduces the fundamental innovation of being completely automatic, without any adjustment required to the user. Such a technique is based on the simultaneous and independent excitation of the sensor at two different frequencies, and on the use of two separate feedback loops. Preferably, one first frequency is the series resonant frequency of the sensor, while the second frequency is lower than the series resonant frequency of the sensor.

The invention further relates to a device for determining the value of the resonant frequency of a resonant sensor subject to a load, in accordance to claim 11.

The oscillator circuit of the device according to the present invention proposes and implements a technique to obtain an active and automatic compensation of the sensor parallel capacitance, and to maintain the oscillation frequency of the circuit constantly equal to the frequency where the phase of the sensor impedance is null. Under the condition of neutralization of the parallel capacitance, such a frequency exactly corresponds to the sensor resonant frequency, irrespective of the degree of damping. Moreover, the circuit automatically follows the above frequency, thereby providing an accurate and reliable measurement of the sensor response.

The excitation at the lower frequency and the first feedback loop enable to detect the sensor response due to the parallel capacitance only. By properly processing such a response, the automatic cancellation of the parallel capacitance is performed. In this condition, the second feedback loop, which is a phase-locked loop (PLL), allows to keep the higher frequency constantly locked to the sensor resonant frequency.

In addition to the instantaneous values of the sensor resonant frequency and damping, the circuit advantageously provides an output parameter related to the value of the compensated capacitance.

Thanks to the characteristics of the method and the device according to the present invention, it is possible to continuously measure the evolution of the parallel capacitance in case of changes of it during the course of a measuring experiment. This may be particularly important in specific applications.

### BRIEF DESCRIPTION OF THE DRAWINGS

Further characteristics and advantages of the present invention will be more clear by the following description, made with illustrative and not limiting purposes, with reference to the attached schematic drawings, in which:

FIG. 1 is a detailed electrical diagram representing the equivalent circuit of a quartz crystal resonant sensor subject to acousto-mechanical and dielectric loading;

FIG. 2 is a simplified electrical diagram of the same equivalent circuit of FIG. 1; and

FIG. 3 is an electrical block diagram of a device according to a possible embodiment of the present invention.

### MODES FOR CARRYING OUT THE INVENTION

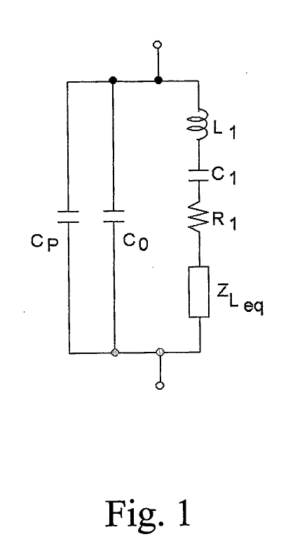

A quartz crystal resonant sensor subject to both acousto-mechanical and dielectric loading can be represented around its fundamental resonant frequency by the equivalent circuit of FIG. 1 (extended BVD model).

In the circuit, the components L₁, C₁ and R₁ form the mechanical (i.e. motional) branch of the model and represent the equivalents of mass, elastic compliance, and mechanical losses, respectively, of the unloaded sensor. The capacitor C₀ represents the dielectric behavior of the sensor associated to the crystal capacitance.

The acousto-mechanical load is represented by the equivalent impedance Z_{Leq}, while C_{P} is the additional capacitance arising from contact with, or immersion into, a liquid whose conductivity is assumed to be negligible.

More specifically, Z_{Leq} can be purely inductive in the case of simple mass accumulation, or complex when an appreciable damping is also present, such as for instance in case of dense and viscous liquids or with viscoelastic films placed on the sensor.

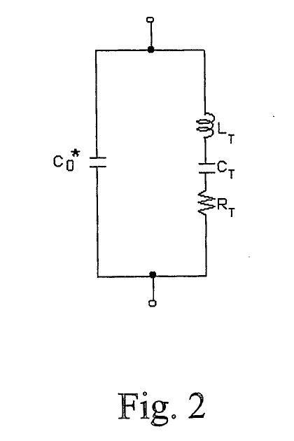

The quantity of primary interest because it directly relates to the load and it is not influenced by stray capacitances in parallel to the sensor, is the series resonant frequency fₛ given by:

$${f}_{s} = \frac{1}{2 π \sqrt{{L}_{T} {C}_{T}}} \qquad ( 1 )$$

where L_{T} and C_{T} respectively represent the total, i.e. inclusive of the load, inductance and capacitance in the motional branch of the sensor equivalent circuit, as resulting from the simplified electric diagram of the equivalent circuit shown in FIG. 2.

In this diagram, the parallel, or static, capacitance is indicated by the capacitor C₀*, and its value is given by the sum of the capacitances C_{P} and C₀ shown in FIG. 1, that is to say C₀*=C₀+C_{P}.

Typical values of fₛ are in the order of 5-30 MHz, depending on the thickness of the particular sensor used.

In order to determine the amount of dissipation losses at the frequency fₛ caused by the total resistance R_{T}, it is also useful to measure the degree of damping or, equivalently, the quality factor Q given by:

$$Q = \frac{2 π {f}_{s} {L}_{T}}{{R}_{T}} = \frac{1}{2 π {f}_{s} {C}_{T} {R}_{T}} \qquad ( 2 )$$

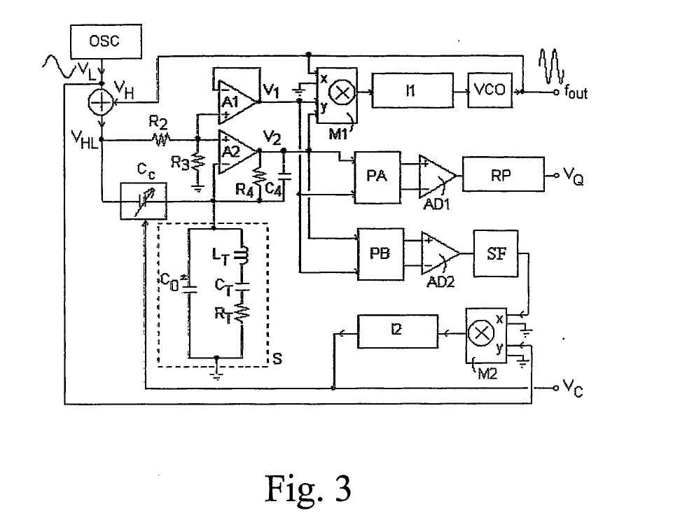

The block diagram of a device according to a possible embodiment of the present invention is shown in FIG. 3.

The sensor, represented by its equivalent circuit inclusive of the load (FIG. 2), is included within the dashed frame S.

The block named C_{C} represents a variable capacitance whose value is controlled by the voltage V_{C}. To implement such a variable capacitance, a fixed capacitance connected in series to the output of a voltage amplifier with a voltage-controlled gain can be used for instance. As an alternative, other known circuit schemes can be used, including for instance a varactor (or varicap) diode, or any devices and configurations able to provide a voltage-controlled variable capacitance.

The voltage waveform V_{HL} is the sum of the sinusoidal signal V_{L} having a preset frequency f_{L} generated by the oscillator OSC, and of the sinusoidal signal V_{H} having a frequency f_{H} generated by the voltage-controlled oscillator VCO.

The frequency f_{H} of the signal V_{H} is taken as the output frequency fₒᵤₜ of the whole oscillator circuit, and it will be shown below that it is constantly maintained equal to the sensor series resonant frequency fₛ. Preferably, the frequency f_{L} is lower than f_{H}. For example, in the experimental tests performed with 10-MHz resonant sensors (f_{H}=10 MHz), the frequency f_{L} was set to 50 kHz. Other values of f_{L} can be used as well, provided that they are suitably lower than the frequency f_{H} to make the discrimination between such two frequencies effective, and therefore make the following considerations valid.

Assuming to avoid the use of particularly selective filters, which tend to be complex and costly, the upper limit for f_{L} can be reasonably set to a couple of decades lower than the sensor resonant frequency.

As far as the basic principle of the proposed method is concerned, the frequency f_{L} might be as well chosen of a suitably larger value than the sensor resonant frequency. However, such a choice would cause practical problems related to the need for operating part of the circuit at very high frequency (in the order of tens or hundreds megahertz), which would in turn introduce critical issues that are instead avoided by the adopted choice.

In the frequency domain, the differential voltage (V₂−V₁) is related to the voltage V_{HL} through the following expression:

$${V}_{2} - {V}_{1} = {V}_{HL} {Z}_{4} α [ {Y}_{T} + j ω {C}_{0}^{*} - j ω {C}_{C α} ] \\ where \text{:} \\ • {C}_{C α} = [ 1 / α - 1 ] {C}_{C} \\ • {Z}_{4} = \frac{{R}_{4}}{1 + j ω {R}_{4} {C}_{4}} \\ • α = \frac{{R}_{3}}{{R}_{2} + {R}_{3}} \\ • {Y}_{T} = {[ j ω {L}_{T} + {R}_{T} + \frac{1}{j ω {C}_{T}} ]}^{- 1} \qquad ( 3 )$$

The values of R₄ and C₄ are properly chosen so that the impedance Z₄ be dominated by R₄ at the lower frequency f_{L}, and by C₄ at the higher frequency f_{H}.

The expression (3) simplifies in two different expressions when it is considered at either the lower frequency f_{L} or the higher frequency f_{H}.

At frequency f_{L} the sensor is far from the resonance and its equivalent circuit reduces to the parallel capacitance C₀*. The expression (3) therefore becomes:
V₂−V₁=jωV_{L}R₄α(C₀*−C_{Cα}] (4)

The expression (4) shows that, by adjusting the compensating capacitance Cc, it is possible to reach the condition where the capacitance C₀* is neutralized by C_{Cα} by means of the detection of the situation where the differential voltage (V₂−V₁) is zero.

This is performed in an automatic and continuous way by the part of the circuit that uses the blocks PB, AD2, SF, M2, I2, and Cc, to implement a feedback loop that keeps locked to the condition (V₂−V₁)=0.

In fact, the low-pass filter PB extracts from the signal (V₂−V₁) the component at the low frequency f_{L} corresponding to the expression (4). Such a component of the signal (V₂−V₁) is amplified by the differential amplifier AD2. The 90° phase shifter SF and the analog multiplier M2 perform a synchronous detection of the component of (V₂−V₁) at the frequency f_{L}, and transform the component in quadrature with respect to V_{L} into a DC voltage.

The integrator 12 forces the output of the analog multiplier M2 to zero, thereby constantly nulling the static error in the loop. The DC output voltage V_{C} of the integrator 12 adjusts the variable capacitance Cc. In this way, the sensor parallel capacitance C₀* is automatically and constantly compensated by the capacitance C_{Cα}. The DC voltage V_{C} is taken as an additional output to provide an instantaneous value of the compensated parallel capacitance C₀*.

At the frequency f_{H}, thanks to the above described method of automatic compensation of the capacitance C₀*, the expression (3) becomes:

$${V}_{2} - {V}_{1} = \frac{α {V}_{H}}{j ω {C}_{4}} {( j ω {L}_{T} + {R}_{T} + \frac{1}{j ω {C}_{T}} )}^{- 1} \qquad ( 5 )$$

The multiplier M1, integrator 11, and voltage-controlled oscillator VCO together form a phase-locked loop (PLL) feedback system.

In fact, the multiplier M1 transforms the component of the differential voltage (V₂−V₁) in quadrature with respect to V_{H} at the frequency f_{H} into a DC voltage that is constantly forced to zero by the integrator 11. To occur this condition, the output frequency fₕ of the oscillator VCO is kept necessarily to the frequency at which the conductance Y_{T} of the sensor is purely real. Such frequency is the same of the series resonant frequency fₛ.

Therefore, the output frequency fₒᵤₜ, that is f_{H}, is constantly equal to fₛ, irrespective of the loading conditions.

The high-pass filter PA, differential amplifier AD1, and peak rectifier RP form a circuit section dedicated to the measurement of the sensor dissipation at resonance.

In fact, the high-pass filter PA extracts from the signal (V₂−V₁) the component at the higher frequency f_{H′} which by means of the two above described feedback loops is constantly kept equal to the resonant frequency fₛ. Therefore, the amplitude of such a component of the signal (V₂−V₁) is proportional to the term 1/R_{T} or, equivalently, to the quality factor Q of the sensor, as expressed by equation (2). The peak rectifier RP then provides a DC voltage proportional to 1/R_{T} that is taken as a further additional output of the whole circuit.

Experimental Results

A prototype of a device including an oscillator based on the electric diagram of FIG. 3 was assembled using commercially-available components selected among those having proper characteristics. In the prototype, the variable capacitance was implemented as described above, that is by means of a fixed capacitance connected in series to the output of a voltage amplifier with a voltage-controlled gain.

As the piezoelectric resonant sensors, 10-MHz AT-cut TSM quartz crystals were used. The frequency of the signal V_{L} was set to 50 kHz. The sensors were immersed into four liquids determining different loading conditions, namely acetone, trichloroethylene, ethanol, and ethylene glycol.

As a preliminary step, the differences between the exact unloaded series resonant frequency fₛ of the sensors, nominally equal to 10 MHz, and the corresponding frequency values in each of the four loading conditions were measured by means of an impedance analyzer and the obtained results were considered as the reference values (Δfₛ reference in Hz).

Therefore, a second test was performed with the sensors connected to the proposed oscillator circuit in which the parallel capacitance compensation section was disabled, and the oscillator output frequency was measured in the different loading conditions to determine the values of the frequency shift Δfₛ with respect to the unloaded case, and in a third test the oscillator output frequency was measured in the different loading conditions with the parallel capacitance compensation section enabled, and the values of the frequency shift Δfₛ with respect to the unloaded case were determined for comparison. The results of the tests are reported in the following Table 1.

TABLE 1

| | | Trichloro- | | |
|---|---|---|---|---|
| | Acetone | ethylene | Ethanol | Ethylene Glycol |
| Δfₛ reference | 3210 | 5304 | 5462 | 20838 |
| [Hz] | | | | |
| Δfₛ oscillator without | 2750 | 3366 | 3531 | Circuit unable |
| the capacitance | | | | to sustain |
| compensation [Hz] | | | | oscillations |
| Δfₛ oscillator with the | 3232 | 4942 | 5375 | 20529 |
| capacitance | | | | |
| compensation enabled | | | | |
| [Hz] | | | | |
| Relative error of Δfₛ | 14.3% | 36.5% | 35.3% | — |
| without the | | | | |
| capacitance | | | | |
| compensation | | | | |
| Relative error of Δfₛ | 0.7% | 6.8% | 1.6% | 1.5% |
| with the capacitance | | | | |
| compensation enabled | | | | |
| Controlling voltage V_{C} | 365 | 319 | 389 | 518 |
| of the compensating | | | | |
| capacitance C_{C} [mV] | | | | |
| Value of the | 9.92 | 7.81 | 11.02 | 16.92 |
| compensating | | | | |
| capacitance C_{C} [pF] | | | | |

In addition to the percent errors occurred in the second and third tests with the proposed oscillator circuit, Table 1 also reports in the last two rows the measured values of the voltage V_{C} and the correspondent values of the compensating capacitance C_{C}.

The following Table 2 reports the corresponding values between the compensating capacitance C_{C} and the controlling voltage V_{C} measured in the circuit.

TABLE 2

| Capacitance C_{C} [pF] | Voltage V_{C} [mV] |
|---|---|
| 2.10 | 191 |
| 3.85 | 231 |
| 5.43 | 268 |
| 6.65 | 295 |
| 8.21 | 330 |
| 8.75 | 342 |
| 10.20 | 375 |
| 12.07 | 417 |
| 12.40 | 420 |
| 13.64 | 455 |
| 15.04 | 485 |
| 16.85 | 527 |
| 18.20 | 555 |
| 20.91 | 604 |
| 21.93 | 641 |
| 24.85 | 707 |
| 26.50 | 743 |
| 30.14 | 828 |
| 32.87 | 887 |
| 39.30 | 994 |

The experimental results shown in Table 1 demonstrate that the device according to the invention with the automatic capacitance compensation system enabled provides an accuracy improvement of more than one order of magnitude over the uncompensated case. Moreover, the oscillator operates correctly with high metrological performances even when loaded by ethylene glycol, which is a liquid that, due to the high dielectric constant and induced damping prevents the circuit from sustaining oscillations in the absence of capacitance compensation.

Moreover, the data in the last two rows of Table 1 show that the oscillator, by means of the voltage V_{C} and the relationship with the compensating capacitance C_{C}, is capable to determine the value of the compensated parallel capacitance C₀*. As expected, such a value increases with increasing the dielectric permittivity of the liquid. The basic principles of the present invention are not limited to the quartz sensors herein described as an example, but they can as well find application with piezoelectric resonant sensors in general.

1. A method to determine the value of the resonant frequency of a resonant sensor subject to an acousto-mechanical and/or dielectric load, wherein said sensor is excited by at least a first electrical signal having a first frequency, characterized in that the sensor is constantly and simultaneously excited by at least a second electrical signal having a second frequency different and independent from said first frequency so as to compensate the parallel capacitance of the sensor in an automatic and continuous way.

2. A method according to claim 1, wherein said first frequency of said first electrical exciting signal of said sensor is constantly maintained to a value such that the phase of the impedance of said sensor is zero.

3. A method according to claim 1, wherein said second electrical signal at said second frequency is used to instantaneously determine the response due only to the parallel capacitance of said sensor.

4. A method according to claim 1, wherein said first frequency is the series resonant frequency of the sensor.

5. A method according to claim 1, wherein said second frequency is lower than the series resonant frequency of the sensor.

6. A method according to claim 1, wherein instantaneous detection is provided of at least one electrical quantity representative of the value of said compensated parallel capacitance.

7. A method according to claim 1, wherein instantaneous detection is provided of at least one electrical quantity representative of the value of the quality factor Q of said sensor.

8. A method according to claim 1, wherein said resonant sensor is a piezoelectric sensor.

9. A method according to claim 1, wherein said resonant sensor is a piezoelectric quartz sensor.

10. A method according to claim 1, wherein said resonant sensor is a piezoelectric AT-cut vibrating in Thickness-Shear Mode (TSM) quartz crystal sensor.

11. A device to determine the value of the resonant frequency of a resonant sensor subject to anacousto-mechanical and/or dielectric load, including at least one oscillator circuit having at least one first feedback section to excite said sensor with at least one first electrical signal having a first frequency, characterized in that at least one second feedback section is included to constantly and simultaneously excite said sensor with at least one second electrical signal having a second frequency different and independent from said first frequency so as to compensate the parallel capacitance of the sensor in anautomatic and continuous way.

12. A device according to claim 11, wherein said resonant sensor is the frequency-controlling element of the frequency of said oscillator circuit.

13. A device according to claim 11, wherein said first frequency is the series resonant frequency of the sensor.

14. A device according to claim 11, wherein said second frequency is lower than the series resonant frequency of the sensor.

15. A device according to claim 11, wherein said first feedback section includes a first feedback loop that forms a phase-locked loop to follow the series resonant frequency of said sensor.

16. A device according to claim 11, wherein said second feedback section includes a second feedback loop that performs the automatic compensation of the parallel capacitance of said sensor.

17. A device according to claim 15, wherein said first feedback loop is coupled to said second feedback loop.

18. A device according to claim 11, wherein at least one section is included comprising a voltage-controlled variable capacitance.

19. A device according to claim 11, wherein at least one terminal of said resonant sensor is connected to ground.

20. A device according to claim 11, wherein said resonant sensor is a piezoelectric sensor.

21. A device according to claim 11, wherein said resonant sensor is a piezoelectric quartz sensor.

22. A device according to claim 11, wherein said resonant sensor is a piezoelectric AT-cut vibrating in Thickness-Shear Mode (TSM) quartz crystal sensor.
